(19) United States
(12) Patent Application Publication
(10) Pub. No.: US 2026/0144003 A1
(43) Pub. Date: May 21, 2026

(54) SUBSTRATE PROCESSING APPARATUS AND SUBSTRATE PROCESSING METHOD USING THE SAME

(71) Applicant: WONIK IPS CO., LTD., Pyeongtaek-si (KR)

(72) Inventors: Dae Seong LEE, Pyeongtaek-si (KR); Won Jun JANG, Pyeongtaek-si (KR); Dong Jae LEE, Pyeongtaek-si (KR); Myung Keun OH, Pyeongtaek-si (KR); Joo Suop KIM, Pyeongtaek-si (KR); Won Sik AHN, Pyeongtaek-si (KR); Hae Jin AHN, Pyeongtaek-si (KR)

(21) Appl. No.: 19/266,712

(22) Filed: Jul. 11, 2025

(30) Foreign Application Priority Data
Nov. 21, 2024 (KR) 10-2024-0167218

(51) Int. Cl. H01L 21/677

(52) U.S. Cl. CPC H10P 72/3312; H10P 72/3302

(57) ABSTRACT

A substrate processing apparatus comprises: a substrate support unit (100) including a boat (110) that supports a plurality of substrates (1) stacked in a vertical direction; a substrate loading unit (200) forming a loading space (S1) where the substrates (1) are loaded into and unloaded from the boat (110); a reaction tube unit (300) forming a processing space (S2) therein for processing the substrates (1) introduced through the boat (110) in communication with the loading space (S1); a boat driving unit (400) that moves the substrate support unit (100) vertically between the loading space (S1) and the processing space (S2) and rotates the boat (110) around a virtual vertical rotation axis; and a controller that controls the driving of the boat (110) through the boat driving unit (400).

### CROSS-REFERENCE TO RELATED APPLICATIONS

This U.S. non-provisional patent application claims priority under 35 U.S.C. § 119 of Korean Patent Application No. 10-2024-0167218, filed on Nov. 21, 2024, the entire contents of which are hereby incorporated by reference.

### FIELD OF THE INVENTION

The present invention relates to a substrate processing apparatus and a substrate processing method using the same, and more particularly, to a substrate processing apparatus for batch-processing a plurality of substrates and a substrate processing method using the same.

### BACKGROUND ART

Generally, a substrate processing apparatus is an apparatus for performing processes such as deposition, etching, and heat treatment on a substrate, and is classified into a vertical batch-type apparatus that loads a plurality of substrates and performs processing in batches, and a single-wafer type apparatus that introduces a single substrate and performs substrate processing.

Generally, in the case of a vertical batch-type substrate processing apparatus, it includes a substrate loading unit where a boat loaded with a plurality of substrates is located in a vertical direction and which forms a loading space for loading substrates into the boat or unloading substrates from the boat, and a substrate processing unit that performs substrate processing by raising and introducing the boat loaded with a plurality of substrates from above the substrate loading unit.

At this time, in the conventional substrate processing apparatus, after raising the boat into the substrate processing unit, the boat was rotated during the process to perform uniform processing on the substrate. However, even with such control, there is a problem that the uniformity of film thickness among a plurality of substrates and the uniformity of film thickness by region within a single substrate are low.

In particular, the conventional substrate processing apparatus has a problem in that the formation of a native oxide film due to oxygen remaining in the loading space causes variations in film thickness by region within the substrate or among a plurality of substrates.

More specifically, generally, a support region of a substrate that is in contact with and supported by a boat generates temperature deviations due to heat conduction or heat loss through the support part compared to a non-contact region. As inert gas is continuously injected from a specific direction of the stationary boat placed in the loading space, the local temperature drop in a specific region of the boat intensifies, and accordingly, variations in the degree of native oxide film formation by region within the substrate intensify, resulting in non-uniform film thickness.

Furthermore, in this case, by injecting inert gas only from a specific direction into the stationary boat placed in the loading space, airflow cannot be generated behind the rods forming the boat for supporting substrates and becomes stagnant. As a result, a native oxide film is formed, and the non-uniformity of the thin film thickness gradually worsens.

In addition, the conventional substrate processing apparatus has a problem that temperature uniformity is lowered and non-uniformity in thin film thickness occurs as it is vertically moved and placed in the loading space while maintaining a fixed direction in areas other than the processing space.

### SUMMARY OF THE INVENTION

The object of the present invention is to provide a substrate processing apparatus capable of uniform substrate processing and a substrate processing method using the same, in order to solve the above problems.

The present invention has been created to achieve the above object of the present invention. The present invention discloses a substrate processing apparatus comprising: a substrate support unit (100) including a boat (110) that supports a plurality of substrates (1) stacked in a vertical direction; a substrate loading unit (200) forming a loading space (S1) where the substrates (1) are loaded into and unloaded from the boat (110); a reaction tube unit (300) forming a processing space (S2) therein for processing the substrates (1) introduced through the boat (110) in communication with the loading space (S1); a boat driving unit (400) that moves the substrate support unit (100) vertically between the loading space (S1) and the processing space (S2) and rotates the boat (110) around a virtual vertical rotation axis; and a controller that controls the driving of the boat (110) through the boat driving unit (400), wherein the controller controls the boat (110) to rotate during at least one of vertical upward and downward movements of the boat (110).

The controller may control the boat (110) such that rotation is accompanied when the boat (110) moves downward from the processing space (S2) to the loading space (S1), and rotation ends when the downward movement to the loading space (S1) is completed.

The controller may control the boat (110) such that rotation continues for a preset time after the boat (110) descends and reaches the loading space (S1).

The controller may control the boat (110) such that rotation starts when the boat (110) begins to ascend to the processing space (S2), and rotation is accompanied when the boat (110) moves upward from the loading space (S1) to the processing space (S2).

The controller may control the boat (110) to rotate within the loading space (S1) for a preset time before the boat (110) begins to ascend to the processing space (S2).

The controller may control the boat (110) such that rotation continues during the process in which the boat (110) is introduced into the processing space (S2) and the substrates (1) are processed.

The controller may control the boat (110) such that rotation continues from the moment the boat (110) begins to ascend to the processing space (S2) until the moment the downward movement to the loading space (S1) is completed.

The controller may control at least one of the rotation speed during upward movement and the rotation speed during downward movement between the loading space (S1) and the processing space (S2) to be smaller than the rotation speed of the boat (110) within the processing space (S2).

The controller may control the rotation speed within the loading space (S1) to be greater than the rotation speed of the boat (110) within the processing space (S2).

The controller may control the rotation speed after descending from the processing space (S2) to the loading space (S1) to be greater than the rotation speed of the boat (110) within the processing space (S2).

The controller may control the boat (110) to rotate within the loading space (S1) for a preset time before the boat (110) begins to ascend to the processing space (S2), and may control the rotation speed in the loading space (S1) after the boat (110) completes its descent to be greater than the rotation speed in the loading space (S1) before the boat (110) begins to ascend.

The apparatus may further include a cooling gas supply unit (500) installed on one side of the substrate loading unit (200) to inject cooling gas into the loading space (S1).

The reaction tube unit (300) may include a reaction tube (310) forming the processing space (S2), and a temperature control unit (320) disposed around the reaction tube (310) to heat and cool the processing space (S2).

The temperature control unit (320) may heat the processing space (S2) before and after the introduction of the boat (110) into the processing space (S2) according to the upward movement of the substrate support unit (100).

The apparatus may further include one or more gas injection units (600) installed in the reaction tube unit (300) to inject inert gas from one side to the other side of the processing space (S2) during upward movement for the introduction of the boat (110) into the processing space (S2).

The controller may end the rotation of the boat (110) after the temperature of the reaction tube (310) is cooled to preset temperature through the temperature control unit (320).

Further, the present invention discloses a substrate processing method comprising: a boat ascending step (S100) of raising the substrate support unit (100) to introduce the boat (110) into the processing space (S2); a process step (S200) of performing processing on the substrates (1) in the processing space (S2) through the reaction tube unit (300); and a boat descending step (S300) of lowering the substrate support unit (100) after the process step (S200) to position the boat (110) in the loading space (S1), wherein the boat (110) rotates during at least one of the boat ascending step (S100) and the boat descending step (S300).

The boat ascending step (S100) may involve injecting inert gas from one side to the other side of the processing space (S2).

The boat ascending step (S100) may include a pre-rotation step (S110) of rotating the boat (110) disposed in the loading space (S1), and an introduction step (S120) of raising the substrate support unit (100) to the processing space (S2) while maintaining the rotation of the boat (110) after the pre-rotation step (S110), thereby introducing the boat (110) into the processing space (S2).

In the process step (S200), the boat (110) rotates for at least a portion of time, and in the introduction step (S120), the boat (110) may rotate at a speed smaller than the rotation speed of the boat (110) rotating during the process step (S200).

The boat descending step (S300) may include an unloading step (S310) of lowering the substrate support unit (100) to the loading space (S1) while maintaining the rotation of the boat (110), thereby unloading the boat (110) to the loading space (S1), and a subsequent rotation step (S320) of rotating the boat (110) located in the loading space (S1) after the unloading step (S310).

The subsequent rotation step (S320) may involve injecting cooling gas from one side of the substrate loading unit (200) into the loading space (S1).

In the process step (S200), the boat (110) rotates for at least a portion of time, and in the subsequent rotation step (S320), the boat (110) may rotate at a speed greater than the rotation speed of the boat (110) rotating during the process step (S200).

The process step (S200) may include: a temperature rising step (S210) of raising the temperature of the processing space (S2) from a first temperature (T1) to a second temperature (T2) after the boat (110) is introduced into the processing space (S2) according to the boat ascending step (S100); a process performing step (S220) of performing processing on the substrates (1); and a temperature descending step (S230) of lowering the temperature of the processing space (S2) to the first temperature (T1) after the process performing step (S220).

The process performing step (S220) may include: a pressure rising step (S221) of raising the pressure of the processing space (S2) from a low pressure lower than normal pressure (atmospheric pressure), to a high pressure higher than normal pressure; and a pressure maintaining step (S222) of maintaining the pressure of the processing space (S2) in a high-pressure state after the pressure rising step (S221).

Rotation of the boat (110) may be continuously maintained during the boat ascending step (S100), the process step (S200), and the boat descending step (S300).

The substrate processing apparatus and the substrate processing method using the same according to the present invention have the advantage of improving temperature uniformity for a plurality of substrates by accompanying rotation during the vertical movement of the boat, thereby improving the uniformity of film thickness.

Further, the substrate processing apparatus and the substrate processing method using the same according to the present invention have the advantage that uniform film thickness can be maintained by inducing relatively even injection of cooling gas injected from a specific direction through the rotation of the boat in the loading space, thereby preventing temperature deviation within the boat and airflow stagnation within a specific region, and minimizing local native oxide film formation.

Further, the substrate processing apparatus and the substrate processing method using the same according to the present invention have the advantage of increasing the overall uniformity of film thickness by inducing the boat to be uniformly affected by environmental changes between the loading space and the processing space during the upward and downward movements, due to rotation during the upward and downward movements of the boat.

### BRIEF DESCRIPTION OF THE DRAWINGS

FIG. 1 is a view showing a state where a substrate support unit of a substrate processing apparatus according to the present invention is raised.

FIG. 2 is a view showing a state where a substrate support unit of the substrate processing apparatus according to FIG. 1 is lowered.

FIG. 3 is a graph showing changes in temperature and pressure of a processing space according to time in the substrate processing apparatus according to FIG. 1.

FIG. 4 is a flowchart showing a substrate processing method according to the present invention.

### DETAILED DESCRIPTION OF THE PREFERRED EMBODIMENTS

Hereinafter, the substrate processing apparatus and the substrate processing method using the same according to the present invention will be described in detail with reference to the accompanying drawings.

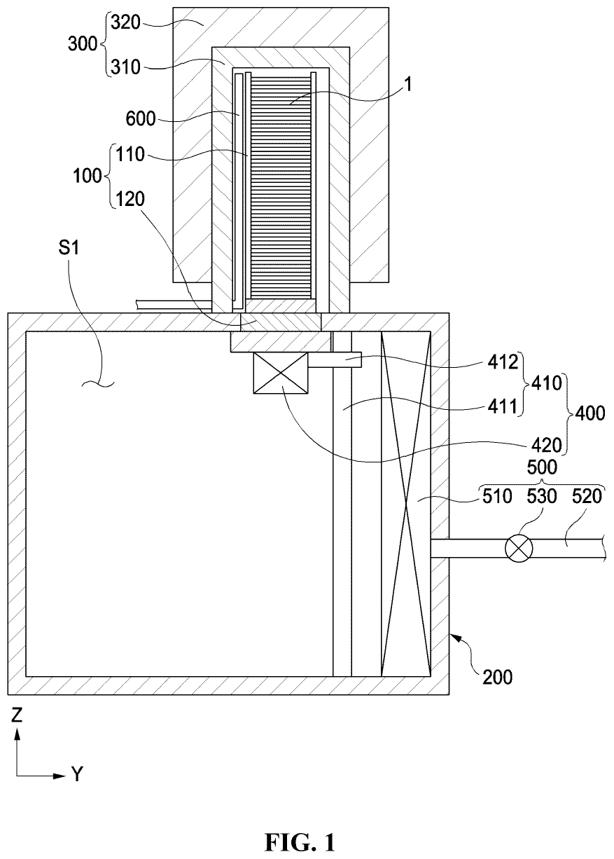

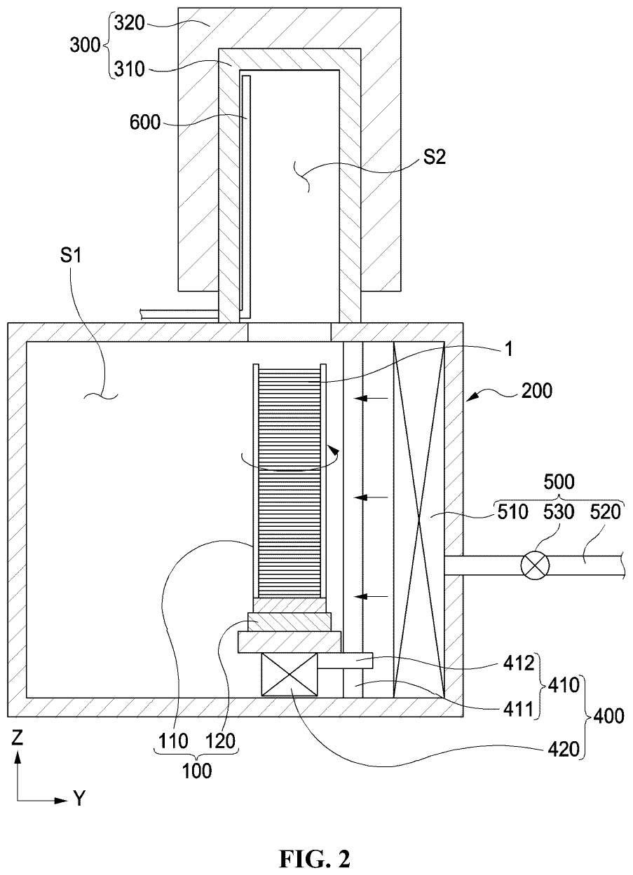

As shown in FIGS. 1 and 2, the substrate processing apparatus according to the present invention includes: a substrate support unit (100) including a boat (110) that supports a plurality of substrates (1) stacked in a vertical direction; a substrate loading unit (200) forming a loading space (S1) where the substrates (1) are loaded into and unloaded from the boat (110); a reaction tube unit (300) forming a processing space (S2) therein for processing the substrates (1) introduced through the boat (110) in communication with the loading space (S1); and a boat driving unit (400) that moves the substrate support unit (100) vertically between the loading space (S1) and the processing space (S2) and rotates the boat (110) around a virtual vertical rotation axis; and a controller that controls the driving of the boat (110) through the boat driving unit (400).

Further, the substrate processing apparatus according to the present invention may further include a cooling gas supply unit (500) installed on one side of the substrate loading unit (200) to inject cooling gas into the loading space (S1).

Further, the substrate processing apparatus according to the present invention may further include one or more gas injection units (600) installed in the reaction tube unit (300) to inject inert gas from one side to the other side of the processing space (S2) during upward movement for introduction of the boat (110) into the processing space (S2).

Here, the substrates (1) to be processed can be understood to include all substrates, such as display substrates used in display devices like LEDs, LCDs, OLEDs, semiconductor substrates, solar cell substrates, and glass substrates.

The substrates (1) may be loaded into a FOUP (Front-opening Unified Pod) and transferred in multiple units at once, and the FOUP may be a front-opening pod capable of loading substrates (1) in certain quantity units.

In particular, the substrates (1) subject to processing according to the present invention may include 50 or more substrates (1) stacked in a vertical direction and processed simultaneously, and for this purpose, may be stored and moved through FOUPs in which a plurality of substrates (1) are stacked.

The substrate support unit (100) is a component that includes a boat (110) that supports a plurality of substrates (1) stacked in a vertical direction, and various configurations are possible.

That is, the substrate support unit (100) may move between the loading space (S1) and the processing space (S2) to introduce the substrates (1) to be processed into the processing space (S2), and may guide the processed substrates (1) to be positioned in the loading space (S1) for unloading.

To this end, the substrate support unit (100) may include a boat (110) that supports a plurality of substrates (1) stacked in a vertical direction, and a cap flange (120) that supports the boat (110) from below the boat (110) and is brought into close contact with the reaction tube unit (300) upon ascent, thereby introducing the boat (110) into the processing space (S2) and simultaneously sealing the processing space (S2).

In this case, the cap flange (120) may be connected to a moving block (412), described later, to move vertically through a vertical driving unit (410), and may be configured such that a rotation driving unit (420) is installed at a lower part thereof.

The boat (110) is a component that supports a plurality of substrates (1) to be spaced apart from each other vertically, and may include at least three vertical rods on the cap flange (120), and a plurality of support parts formed in the inner surface of the vertical rods to support the substrates (1).

In this case, the boat (110) may penetrate the fixed cap flange (120) and be connected to a rotation driving unit (420), described later, and may rotate around a vertical rotation axis passing through the center in a plane by the rotation driving unit (420).

The substrate loading unit (200) is a component where a loading space (S1) for loading and unloading substrates (1) from/to the boat (110) is formed, and various configurations are possible.

That is, the substrate loading unit (200) can transfer substrates from the aforementioned FOUPs through a transfer robot, thereby transferring substrates between the boat (110) and the FOUPs.

In particular, the substrate loading unit (200) may have a substrate support unit (100) including a boat (110) installed therein to be vertically movable such that it ascends to be introduced into the processing space (S2) and descends to be positioned in the loading space (S1), and a transfer robot for substrate transfer may also be installed.

Meanwhile, the substrate loading unit (200) may perform gas supply and exhaust to the loading space (S1) where substrates are loaded into and unloaded from the boat (110), and accordingly, the pressure and internal atmosphere of the loading space (S1) can be controlled.

Further, the substrate loading unit (200) may form a loading space (S1) therein and a boat driving unit (400), described later, may be installed therein. Furthermore, a cooling gas supply unit (500) may be provided on a preset inner surface to allow cooling gas to be injected into the loading space (S1).

Thereby, the substrate loading unit (200) can load a plurality of substrates (1) into the boat (110) in the internal loading space (S1), or unload processed substrates (1) from the boat (110). Furthermore, the substrate support unit (100) can be cooled through a cooling gas supply unit (500), described later, when it is lowered and positioned from the processing space (S2).

Further, the substrate loading unit (200) may be a waiting space where the substrate support unit (100) temporarily waits before ascending to the processing space (S2), or before unloading the substrates (1) after the substrate support unit (100) descends from the processing space (S2). During this period, the boat (110) may rotate.

Meanwhile, the substrate loading unit (200) may maintain the oxygen concentration in the loading space (S1) below a preset reference value when the substrate support unit (100) loaded with the substrates (1) to be processed or the processed substrates (1) is located in the loading space (S1), thereby minimizing native oxide film formation on the substrates (1). For this purpose, the loading space (S1) may be replaced with an inert gas functioning as a cooling gas.

Further, as another example, the substrate loading unit (200) may also have outside air introduced without replacement by a separate inert gas, depending on the process.

The reaction tube unit (300) is a component in which a processing space (S2) for processing the substrates (1) introduced through the boat (110) is formed in communication with the loading space (S1), and various configurations are possible.

That is, the reaction tube unit (300) is a component disposed such that a processing space (S2) communicating with the loading space (S1) is formed above the substrate loading unit (200). As the substrate support unit (100) ascends, the processing space (S2) is sealed through the cap flange part (120), and simultaneously, the boat (110) loaded with a plurality of substrates (1) is introduced therein to perform substrate processing.

To this end, the reaction tube unit (300) may include a reaction tube (310) forming the processing space (S2), and a temperature control unit (320) disposed around the reaction tube (310) to heat and cool the processing space (S2).

The temperature control unit (320) may be configured as an insulation part including a plurality of heating elements, and may be disposed to surround the reaction tube (310) and form a space between itself and the reaction tube (310). By applying power to the heating elements to generate heat, the temperature of the processing space (S2) can be raised to a process temperature atmosphere.

Further, the temperature control unit (320) may be configured to inject a refrigerant into the space between itself and the reaction tube (310), thereby cooling the reaction tube (310) and the processing space (S2) and controlling the temperature when cooling the processing space (S2) and the reaction tube (310).

Meanwhile, the temperature control unit (320) may heat the processing space (S2) by maintaining heat generation through the heating elements before and after the introduction of the boat (110).

In this case, the temperature control unit (320) may heat the processing space (S2) before and after the introduction of the boat (110) to maintain the temperature constant at a first temperature (T1) or to raise the temperature. Accordingly, temperature stability for the boat (110) during the introduction process of the boat (110) can be maintained.

That is, the temperature control unit (320) may heat the processing space (S2) before and after the introduction of the boat (110) to raise the temperature, and may also maintain the temperature constant at a first temperature (T1).

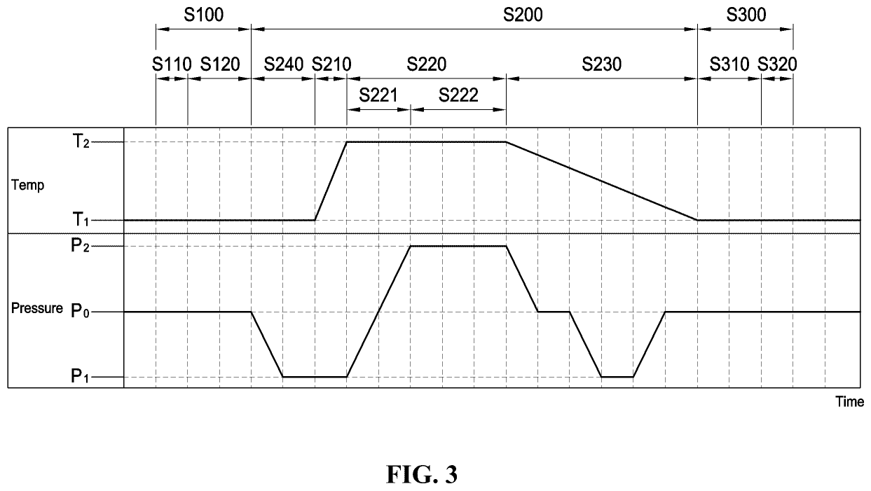

More specifically, as shown in FIG. 3, the temperature control unit (320) may maintain the temperature of the processing space (S2) constant at a first temperature (T1) before and after the boat (110) is introduced into the processing space (S2), and thereafter, may raise the temperature from the first temperature (T1) to a second temperature (T2) for the process.

Further, as shown in FIG. 3, the temperature control unit (320) may maintain the temperature atmosphere in the processing space (S2) by maintaining the second temperature (T2) so that processing on the substrates (1) is performed. After the process on the substrates (1) is completed, to cool the reaction tube (310) and the processing space (S2), a refrigerant may be injected into the space between itself and the reaction tube (310) to lower the temperature of the processing space (S2) from the second temperature (T2) to the first temperature (T1).

Meanwhile, in this case, the rotation of the boat (110) may end after the cooling of the reaction tube (310) and the processing space (S2) through the temperature control unit (320) is completed to the first temperature (T1). More specifically, after the cooling through the temperature control unit (320) is completed, the substrate support unit (100) may descend and be positioned in the loading space (S1), and rotation may end after the boat (110) continuously rotates for a preset time.

Further, the reaction tube (310) is a component in which a boat (110) is introduced to form a sealed processing space (S2) for performing processing on the substrates (1), and the pressure of the processing space (S2) may be changed.

More specifically, as shown in FIG. 3, the reaction tube (310) can perform processing on the substrates (1) by depressurizing from a first pressure (P0) to a second pressure (P1), which is a low pressure lower than normal pressure (atmospheric pressure), through a separately provided exhaust system and corresponding pressure adjustment, and thereafter, pressurizing from the second pressure (P1) to a third pressure (P2), which is a high pressure greater than the normal pressure.

In this case, the reaction tube (310) may be maintained at a third pressure (P2) for a certain period of time, and along with cooling of the processing space (S2), it may be depressurized from the third pressure (P2) to a second pressure (P1) via a first pressure (P0), and thereafter, may be maintained at the first pressure (P0) again.

The boat driving unit (400) is a component that moves the substrate support unit (100) vertically between the loading space (S1) and the processing space (S2), and rotates the boat (110) around a virtual vertical rotation axis. Various configurations are possible.

That is, the boat driving unit (400) may move the substrate support unit (100) vertically between the loading space (S1) and the processing space (S2), and may rotate the boat (110) around a virtual vertical line passing through its center as a rotation axis.

For example, the boat driving unit (400) may include a vertical driving unit (410) that moves the substrate support unit (100) vertically, and a rotation driving unit (420) provided in the substrate support unit (100) that rotates the boat (110).

For example, as shown in FIGS. 1 and 2, the vertical driving unit (410) may include a shaft part (411) disposed in the loading space (S1) within the substrate loading unit (200) and rotating, and a moving block (412) that moves vertically according to the rotation of the shaft part (411) and is connected to the substrate support unit (100).

Further, the vertical driving unit (410) may further include a guide that guides the vertical movement of the substrate support unit (100), thereby inducing stable vertical movement of the substrate support unit (100).

The rotation driving unit (420) is a component provided in the substrate support unit (100) that rotates the boat (110), and various configurations are possible.

For example, the rotation driving unit (420) may be provided at the lower end of the cap flange (120) to be connected to the boat (110), and may be configured to rotationally drive the boat (110) around a vertical rotation axis.

The vertical driving unit (410) and the rotation driving unit (420) may be controlled by control signals through a controller, described later, thereby controlling the vertical movement and rotation of the boat (110) according to the vertical movement of the substrate support unit (100).

The cooling gas supply unit (500) is a component installed on one side of the substrate loading unit (200) to inject cooling gas into the loading space (S1), and various configurations are possible.

For example, the cooling gas supply unit (500) may be a component that injects inert gas as a relatively low-temperature cooling gas into the loading space (S1) for cooling the substrate support unit (100), which descends into the loading space (S1) in a relatively high-temperature state after substrate processing is performed in a high-temperature environment.

In this case, the cooling gas supply unit (500) may inject cooling gas from a preset inner surface of the substrate loading unit (200), thereby inducing the injection of cooling gas and the formation of airflow in a specific direction.

For example, the cooling gas supply unit (500) may include a cooling gas supply pipe (520) installed in the substrate loading unit (200) so as to communicate with the loading space (S1), and a cooling gas supply valve (530) installed in the cooling gas supply pipe (520) to control the supply of cooling gas.

In this case, the cooling gas supply valve (530) may be a simple open/close valve that opens and closes according to a control signal to control the supply of cooling gas. More preferably, it may be configured to control the supply flow rate of cooling gas by adjusting the opening rate of the cooling gas supply valve (530) to control the flow rate of the injected cooling gas.

Meanwhile, the cooling gas supply unit (500) may further include a fan filter unit (510) installed on the inner surface of the substrate loading unit (200) as the front of the cooling gas supply pipe (520), which injects cooling gas supplied from the cooling gas supply pipe (520) towards the loading space (S1) and the substrate support unit (100) placed in the loading space (S1).

In this case, the fan filter unit (510) is a component installed on one side in the substrate loading unit (200) and includes a rotatable fan and a filter provided in front of the fan, and can inject cooling gas transferred through the cooling gas supply pipe (520) toward the loading space (S1).

Meanwhile, any gas such as N2 can be used as the cooling gas for cooling the loading space (S1) and the substrate support unit (120) located in the loading space (S1). For example, it may be composed of a relatively low-temperature inert gas.

Further, as another example, the cooling gas may also be used as a relatively low-temperature outside air containing oxygen, depending on the substrate (1) to be processed and the type of process.

Meanwhile, as described above, the cooling gas supply unit (500) may be a component for lowering the temperature of the relatively high-temperature substrate support unit (100) and the loading space (S1) whose temperature has risen due to it. At the same time, it may also be a component for changing the gas atmosphere of the loading space (S1).

For example, the cooling gas supply unit (500) is a component that supplies and injects inert gas to lower the oxygen concentration in the loading space (S1) within the substrate loading unit (200) and replace it with an inert gas atmosphere, and can directly or indirectly inject inert gas into the loading space (S1).

The gas injection unit (600) is a component installed in the reaction tube unit (300) to inject inert gas from one side to the other side of the processing space (S2) during upward movement for introduction of the boat (110) into the processing space (S2). Various configurations are possible.

That is, the gas injection unit (600) is a nozzle connected to an external gas supply source and installed vertically through the reaction tube unit (300), and may be a component that forms a plurality of injection ports in the longitudinal direction to inject process gas from one side to the other side of the processing space (S2).

In this case, the gas injection unit (600) can inject processing gas used in the process of substrate processing, and inert gas used before, after, and during the process, as process gases.

Meanwhile, the gas injection unit (600) may inject inert gas from one side to the other side of the processing space (S2) during upward movement for introduction of the boat (110) into the processing space (S2). More specifically, when the processing space (S2) is opened for the upward movement of the substrate support unit (100), inert gas can be continuously injected into the processing space (S2) to maintain the inert gas atmosphere within the processing space (S2).

In this case, as shown in FIG. 1, the gas injection unit (600) continuously injects inert gas from a specific lateral side with respect to the boat (110). If the boat (110) ascends and is introduced without accompanying rotation, temperature non-uniformity may occur within the boat (110), which may lead to local native oxide film formation and non-uniformity in substrate processing.

In particular, the gas injection unit (600) continuously supplies relatively low-temperature inert gas into the processing space (S2), which maintains a heated state at a first temperature (T1) through the aforementioned temperature control unit (320), before and after the introduction of the boat (110). Thereby, the temperature uniformity of the boat (110) can be improved through rotation during the introduction of the boat (110), and accordingly, the uniformity of substrate processing can be maintained.

The controller is a component that controls the driving of the boat (110) through the boat driving unit (400), and various configurations are possible.

That is, the controller may be configured to control the vertical driving unit (410) and the rotation driving unit (420) to adjust the vertical movement and rotational movement of the boat (110).

In this case, the controller may control the boat (110) to rotate during at least one of vertical upward and downward movements of the boat (110).

That is, the controller may rotate the boat (110) through the rotation driving unit (420) such that the rotation of the boat (110) is accompanied while the substrate support unit (100) moves from the loading space (S1) to the processing space (S2).

Further, as another example, the controller may rotate the boat (110) through the rotation driving unit (420) such that the rotation of the boat (110) is accompanied while the substrate support unit (100) descends from the processing space (S2) to the loading space (S1), and may also control the boat (110) to rotate during both the upward and downward movements of the substrate support unit (100).

Thereby, the controller, by accompanying rotation during the upward and downward movements of the boat (110), can improve the temperature uniformity of the boat (110) and induce environmental changes in the loading space (S1) and the processing space (S2) to be applied uniformly in each region, thereby leading to overall uniform process performance, pre-processing, and post-processing management.

In this case, the controller may control the boat (110) such that rotation is accompanied when the boat (110) moves downward from the processing space (S2) to the loading space (S1), and rotation ends when the downward movement to the loading space (S1) is completed.

That is, the controller may control the boat (110) such that rotation ends simultaneously with the descent of the boat (110) to the loading space (S1). As another example, the controller may control the boat (110) such that rotation continues for a preset time after the boat (110) descends and reaches the loading space (S1).

Accordingly, by having the controller continuously rotate the boat (110) for a preset time even after the boat (110) has completed its descent into the loading space (S1), it can induce the cooling gas injected through the cooling gas supply unit (500) to reach uniformly, thereby reducing variations in the native oxide film by region and maintaining a uniform film thickness.

Furthermore, through the controller, rotation of the boat (110) continues for a preset time after the boat (110) has completed its descent into the loading space (S1), thereby enhancing the temperature uniformity of the boat (110) within the loading space (S1) and reducing temperature variations by region, thus maintaining a uniform film thickness.

Further, the controller may control the boat (110) such that rotation starts when the boat (110) begins to ascend to the processing space (S2), and rotation is accompanied when the boat (110) moves upward from the loading space (S1) to the processing space (S2). Accordingly, the boat (110) can rotate simultaneously with the upward movement of the substrate support unit (100), so that the rotation of the boat (110) is maintained during the upward process.

Further, as another example, the controller may control the boat (110) to rotate within the loading space (S1) for a preset time before the boat (110) begins to ascend to the processing space (S2).

Further, the controller may control the boat (110) such that rotation continues during the process in which the boat (110) is introduced into the processing space (S2) and the substrates (1) are processed. Thereby, as the boat (110) rotates in the processing space (S2) within the reaction tube (310), temperature uniformity can be achieved and injected gas can be uniformly distributed to each region of the substrate.

Thereby, the controller can induce uniform substrate processing for each substrate.

Meanwhile, in this case, the controller may control the boat (110) such that rotation continues from the moment the boat (110) begins to ascend to the processing space (S2) until the moment the downward movement to the loading space (S1) is completed. Furthermore, rotation may continue from a preset moment before the boat (110) begins to ascend until a preset moment after the boat (110) completes its descent.

The controller may maintain the rotation speed of the boat (110) uniformly throughout all sections of each period from the boat ascending step (S100) to the boat descending step (S300), or as another example, may vary the rotation speed for each section.

For example, the controller may control at least one of the rotation speed during upward movement and the rotation speed during downward movement between the loading space (S1) and the processing space (S2) to be smaller than the rotation speed of the boat (110) within the processing space (S2).

For example, the controller may control the rotation speed of the boat (110) during descent to be smaller than the rotation speed of the boat (110) within the processing space (S2), and may also control the rotation speed of the boat (110) during ascent to be smaller than the rotation speed of the boat (110) within the processing space(S).

Furthermore, the controller may control the rotation speed of the boat (110) within the loading space (S1) to be greater than at least one of the rotation speeds during descent and ascent. By making the rotation speed of the boat (110) relatively small during vertical movement, it can minimize the displacement of seated and supported substrates (1) due to rotation during vertical movement, and ensure support stability.

Further, the controller may control the rotation speed within the loading space (S1) to be greater than the rotation speed of the boat (110) within the processing space (S2). For example, it may control the rotation speed after descending from the processing space (S2) to the loading space (S1) to be greater than the rotation speed of the boat (110) within the processing space (S2).

That is, the controller can relatively increase the rotation speed within the loading space (S1), especially after the boat (110) has completed its descent into the loading space (S1). This can increase the cooling efficiency for the boat (110) and prevent the deterioration of film thickness uniformity due to local native oxide film formation caused by oxygen remaining in the loading space (S1), thereby improving and maintaining the uniformity of film thickness.

Further, the controller may control the rotation speed in the loading space (S1) after the boat (110) completes its descent to be greater than the rotation speed in the loading space (S1) before the boat (110) begins to ascend.

Thereby, after the processing of the substrates (1) is completed, the controller can relatively increase the rotation speed in the loading space (S1) after the descent of the boat (110) loaded with the heated substrates (1), thereby inducing rapid cooling of the substrates (1) and maintaining uniform film thickness distribution.

Meanwhile, the controller may control the rotation speed in the loading space (S1) before the boat (110) begins to ascend to be relatively slower than the rotation speed in the loading space (S1) after the boat (110) completes its descent, thereby strengthening the positional accuracy and support stability of the loaded substrates (1).

Further, as shown in FIG. 3, the controller may end the rotation of the boat (110) after the temperature of the reaction tube (310) is cooled through the temperature control unit (320), and furthermore, the rotation of the boat (110) may start before the heating of the temperature of the reaction tube (310) through the temperature control unit (320) begins.

Hereinafter, a substrate processing method using the aforementioned substrate processing apparatus will be described in detail with reference to the accompanying drawings.

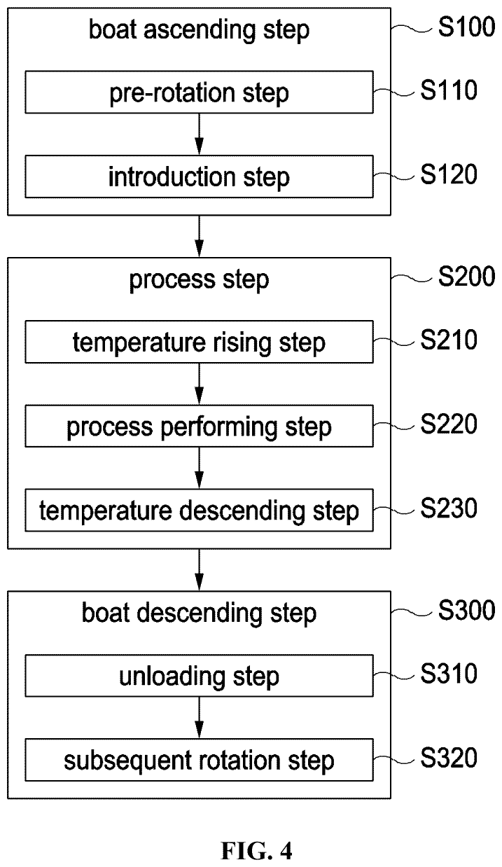

As shown in FIG. 4, the substrate processing method according to the present invention includes: a boat ascending step (S100) of raising the substrate support unit (100) to introduce the boat (110) into the processing space (S2); a process step (S200) of performing processing on the substrates (1) in the processing space (S2) through the reaction tube unit (300); and a boat descending step (S300) of lowering the substrate support unit (100) after the process step (S200) to position the boat (110) in the loading space (S1).

In this case, in the substrate processing method according to the present invention, the boat (110) rotates during at least one of the boat ascending step (S100) and the boat descending step (S300).

That is, the substrate processing method according to the present invention may accompany rotation with the vertical movement of the boat (110) during at least one of the boat ascending step (S100) and the boat descending step (S300).

The boat ascending step (S100) may be a step of raising the substrate support unit (100) to introduce the boat (110) into the processing space (S2).

For example, the boat ascending step (S100) may be a step of introducing the boat (110) into the processing space (S2) by rotating the boat (110) simultaneously with the ascent of the substrate support unit (100).

Further, as another example, the boat ascending step (S100) may include a pre-rotation step (S110) of rotating the boat (110) disposed in the loading space (S1), and an introduction step (S120) of raising the substrate support unit (100) to the processing space (S2) while maintaining the rotation of the boat (110) after the pre-rotation step (S110), thereby introducing the boat (110) into the processing space (S2).

In this case, the pre-rotation step (S110) may be a step of rotating the boat (110) after the substrates (1) are loaded into the loading space (S1), and rotation may be performed at a preset time and rotation speed.

Further, the boat ascending step (S100) may involve injecting inert gas from one side to the other side of the processing space (S2).

More specifically, during the introduction step (S120), inert gas may be injected from one side to the other side of the processing space (S2) through the aforementioned gas injection unit (600).

That is, during the introduction step (S120), by injecting inert gas into the processing space (S2), the inert gas atmosphere within the processing space (S2) can be maintained when the processing space (S2) is opened for the upward movement of the substrate support unit (100).

Meanwhile, in this case, the gas injection unit (600) continuously injects inert gas from a specific lateral side with respect to the boat (110). If the boat (110) ascends and is introduced without accompanying rotation, temperature non-uniformity may occur within the boat (110), which may lead to local native oxide film formation and non-uniformity in substrate processing.

In particular, the gas injection unit (600) continuously supplies relatively low-temperature inert gas into the processing space (S2), which maintains a heated state at a first temperature (T1) through the aforementioned temperature control unit (320), before and after the introduction of the boat (110). Thereby, the temperature uniformity of the boat (110) can be improved through rotation during the introduction step (S120), and accordingly, the uniformity of substrate processing can be maintained.

In the process step (S200), the boat (110) may rotate for at least a portion of time, and in the introduction step (S120), the boat (110) may rotate at a speed smaller than the rotation speed of the boat (110) rotating during the process step (S200).

The process step (S200) may be a step of performing processing on the substrates (1) in the processing space (S2) through the reaction tube unit (300).

For example, the process step (S200) may include: a process preparation step (S240) of adjusting the pressure in the processing space (S2) to prepare for performing a process in the processing space (S2); a temperature rising step (S210) of raising the temperature of the processing space (S2) from a first temperature (T1) to a second temperature (T2) after the boat (110) is introduced into the processing space (S2) according to the boat ascending step (S100); a process performing step (S220) of performing processing on the substrates (1); and a temperature descending step (S230) of lowering the temperature of the processing space (S2) to the first temperature (T1) after the process performing step (S220).

In the process preparation step (S240), with the boat (110) introduced into the processing space (S2) according to the boat ascending step (S100), the pressure of the processing space (S2) may be reduced to a first pressure (P1) lower than normal pressure(atmospheric pressure), thereby performing vacuum exhaust for the processing space (S2).

The temperature rising step (S210) may be a step of raising the temperature of the processing space (S2) from a first temperature (T1) to a second temperature (T2) after the boat (110) is introduced into the processing space (S2) according to the boat ascending step (S100).

In this case, the temperature rising step (S210) may raise the temperature in the processing space (S2) from a first temperature (T1) to a second temperature (T2), which is the process temperature, and accordingly, a temperature atmosphere for the process can be formed in the processing space (S2).

The process performing step (S220) may be a step of performing processing on the substrates (1).

For example, the process performing step (S220) may include: a pressure rising step (S221) of raising the pressure of the processing space (S2) from a first pressure (P1), which is a low pressure lower than normal pressure, to a second pressure (P2), which is a high pressure higher than normal pressure; and a pressure maintaining step (S222) of maintaining the pressure of the processing space (S2) in a high-pressure state after the pressure rising step (S221).

Further, processing on the substrates (1) may be performed as the second temperature (T2) is maintained during the process performing step (S220).

The temperature descending step (S230) may be a step of performing cooling for the processing space (S2) after the process performing step (S220).

In this case, the temperature descending step (S230) may lower the temperature of the processing space (S2) to a first temperature (T1) by cooling the reaction tube (310) and the processing space (S2) while the boat (110) is introduced into the processing space (S2) after the processing of the substrates (1) is completed.

The boat descending step (S300) may be a step of lowering the substrate support unit (100) after the process step (S200) to position the boat (110) in the loading space (S1).

For example, in the boat descending step (S300), the rotation of the boat (110) may end simultaneously with the completion of the descent of the substrate support unit (100).

Further, as another example, the boat descending step (S300) may include an unloading step (S310) of lowering the substrate support unit (100) to the loading space (S1) while maintaining the rotation of the boat (110), thereby unloading the boat (110) to the loading space (S1), and a subsequent rotation step (S320) of rotating the boat (110) located in the loading space (S1) after the unloading step (S310).

The subsequent rotation step (S320) is a step in which rotation continues for a preset time after the boat (110) has completed its descent into the loading space (S1), and may involve injecting cooling gas from one side of the substrate loading unit (200) into the loading space (S1).

Further, in the subsequent rotation step (S320), the boat (110) rotates at a speed greater than the rotation speed of the boat (110) rotating during the process step (S200). As described above, this can more effectively maintain the uniformity of the thin film thickness of the processed substrates.

Further, the rotation speed of the boat (110) in the subsequent rotation step (S320) may be greater than the rotation speed of the boat (110) in the pre-rotation step (S110).

Thereby, after the processing of the substrates (1) is completed, the subsequent rotation step (S320) can relatively increase the rotation speed in the loading space (S1) after the descent of the boat (110) loaded with the heated substrates (1), thereby inducing rapid cooling of the substrates (1) and maintaining uniform film thickness distribution.

Further, the pre-rotation step (S110) can strengthen the positional accuracy and support stability of the loaded substrates (1) by making the rotation speed of the boat (110) relatively slower than that in the subsequent rotation step (S320).

Meanwhile, the rotation of the boat (110) may be continuously maintained during the boat ascending step (S100), the process step (S200), and the boat descending step (S300).

The foregoing is merely a description of some of the preferred embodiments that can be implemented by the present invention. As is well known, the scope of the present invention should not be construed as being limited to the above embodiments, and it is understood that all technical ideas that share the technical spirit and fundamental principles of the present invention described above are included within the scope of the present invention.

What is claimed is:

1. A substrate processing apparatus comprising:
a substrate support unit including a boat that supports a plurality of substrates stacked in a vertical direction;
a substrate loading unit forming a loading space where the substrates are loaded into and unloaded from the boat; a reaction tube unit forming a processing space therein for processing the substrates introduced through the boat in communication with the loading space;
a boat driving unit that moves the substrate support unit vertically between the loading space and the processing space and rotates the boat around a virtual vertical rotation axis; and
a controller that controls the driving of the boat through the boat driving unit, wherein the controller controls the boat to rotate during at least one of vertical upward and downward movements of the boat.

2. The substrate processing apparatus according to claim 1, wherein:
the controller controls the boat such that rotation is accompanied when the boat moves downward from the processing space to the loading space, and rotation ends when the downward movement to the loading space is completed.

3. The substrate processing apparatus according to claim 1, wherein:
the controller controls the boat such that rotation continues for a preset time after the boat descends and reaches the loading space.

4. The substrate processing apparatus according to claim 1, wherein:
the controller controls the boat such that rotation starts when the boat begins to ascend to the processing space, and rotation is accompanied when the boat moves upward from the loading space to the processing space.

5. The substrate processing apparatus according to claim 1, wherein:
the controller controls the boat to rotate within the loading space for a preset time before the boat begins to ascend to the processing space.

6. The substrate processing apparatus according to claim 1, wherein:
the controller controls the boat such that rotation continues during the process in which the boat is introduced into the processing space and the substrate is processed.

7. The substrate processing apparatus according to claim 1, wherein:
the controller controls the boat such that rotation continues from the moment the boat begins to ascend to the processing space until the moment the downward movement to the loading space is completed.

8. The substrate processing apparatus according to claim 1, wherein:
the controller controls at least one of the rotation speed during upward movement and the rotation speed during downward movement between the loading space and the processing space to be smaller than the rotation speed of the boat within the processing space.

9. The substrate processing apparatus according to claim 1, wherein:
the controller controls the rotation speed within the loading space to be greater than the rotation speed of the boat within the processing space.

10. The substrate processing apparatus according to claim 1, wherein:
the controller controls the rotation speed after descending from the processing space to the loading space to be greater than the rotation speed of the boat within the processing space.

11. The substrate processing apparatus according to claim 3, wherein:
the controller controls the boat to rotate within the loading space for a preset time before the boat begins to ascend to the processing space, and controls the rotation speed in the loading space after the boat completes its descent to be greater than the rotation speed in the loading space before the boat begins to ascend.

12. The substrate processing apparatus according to claim 1, further comprising: a cooling gas supply unit installed on one side of the substrate loading unit to inject cooling gas into the loading space.

13. The substrate processing apparatus according to claim 1, wherein:
the reaction tube unit includes a reaction tube forming the processing space, and a temperature control unit disposed around the reaction tube to heat and cool the processing space.

14. The substrate processing apparatus according to claim 13, wherein:
the temperature control unit heats the processing space before and after the introduction of the boat into the processing space according to the upward movement of the substrate support unit.

15. The substrate processing apparatus according to claim 1, further comprising:
one or more gas injection units installed in the reaction tube unit to inject inert gas from one side to the other side of the processing space during upward movement for the introduction of the boat into the processing space.

16. The substrate processing apparatus according to claim 13, wherein:
the controller ends the rotation of the boat after the temperature of the reaction tube is cooled through the temperature control unit.

17. A substrate processing method using a substrate processing apparatus comprising:
a substrate support unit including a boat that supports a plurality of substrates stacked in a vertical direction; a substrate loading unit forming a loading space where the substrates are loaded into and unloaded from the boat;
a reaction tube unit forming a processing space therein for processing the substrates introduced through the substrate support unit in communication with the loading space; and
a boat driving unit that moves the boat vertically between the loading space and the processing space and rotates the boat around a virtual vertical rotation axis,
the method comprising:
a boat ascending step of raising the substrate support unit to introduce the boat into the processing space;
a process step of performing processing on the substrates in the processing space through the reaction tube unit; and
a boat descending step of lowering the substrate support unit after the process step to position the boat in the loading space, wherein the boat rotates during at least one of the boat ascending step and the boat descending step.

18. The substrate processing method according to claim 17, wherein:
the boat ascending step involves injecting inert gas from one side to the other side of the processing space.

19. The substrate processing method according to claim 17, wherein:
the boat ascending step includes a pre-rotation step of rotating the boat disposed in the loading space, and an introduction step of raising the substrate support unit to the processing space while maintaining the rotation of the boat after the pre-rotation step, thereby introducing the boat into the processing space.

20. The substrate processing method according to claim 19, wherein:
in the process step, the boat rotates for at least a portion of time; and in the introduction step, the boat rotates at a speed smaller than the rotation speed of the boat rotating during the process step.

21. The substrate processing method according to claim 17, wherein:
the boat descending step includes an unloading step of lowering the substrate support unit to the loading space while maintaining the rotation of the boat, thereby unloading the boat to the loading space, and a subsequent rotation step of rotating the boat located in the loading space after the unloading step.

22. The substrate processing method according to claim 21, wherein:
the subsequent rotation step involves injecting cooling gas from one side of the substrate loading unit into the loading space.

23. The substrate processing method according to claim 21, wherein:
in the process step, the boat rotates for at least a portion of time; and in the subsequent rotation step, the boat rotates at a speed greater than the rotation speed of the boat rotating during the process step.

24. The substrate processing method according to claim 17, wherein:
the process step includes a temperature rising step of raising the temperature of the processing space from a first temperature to a second temperature after the boat is introduced into the processing space according to the boat ascending step; a process performing step of performing processing on the substrate; and a temperature descending step of lowering the temperature of the processing space to the first temperature after the process performing step.

25. The substrate processing method according to claim 24, wherein:
the process performing step includes a pressure rising step of raising the pressure of the processing space from normal pressure, i.e., a low pressure lower than atmospheric pressure, to a high pressure higher than normal pressure, and a pressure maintaining step of maintaining the pressure of the processing space in a high-pressure state after the pressure rising step.

26. The substrate processing method according to claim 17, wherein:
rotation of the boat is continuously maintained during the boat ascending step, the process step, and the boat descending step.
